(19) United States
(12) Patent Application Publication
(10) Pub. No.: US 2007/0124093 A1
(43) Pub. Date: May 31, 2007

(54) Method for locating line-to-ground fault point of underground power cable system

(75) Inventors: Myeong Song Choi, Seoul (KR); Duck Su Lee, Seoul (KR); Xia Yang, Xiangxi (CN)

Correspondence Address: THE WEBB LAW FIRM, P.C., 700 KOPPERS BUILDING, 436 SEVENTH AVENUE, PITTSBURGH, PA, 15219, US

(73) Assignee: MYONGJI UNIVERSITY INDUSTRY AND ACADEMIA COOPERATION FOUNDATION, Gyeonggi-do (KR)

(21) Appl. No.: 11/442,764

(22) Filed: May 30, 2006

(30) Foreign Application Priority Data
Nov. 5, 2005 (KR) 10-2005-0108998

(51) Int. Cl. G01R 31/00

(52) U.S. Cl. 702/59

(57) ABSTRACT

The present invention provides method for locating a line-to-ground fault point of an underground power cable system wherein a distributed parameter circuit analysis theory is employed to consider a capacitive element of a cable in a underground power cable analysis, thereby providing an accurate estimation of the fault distance even when the arrangement of the cable and the fault resistance are varied. A method for locating a line-to-ground fault point of an underground power cable system of the present invention comprises steps of: modeling an equivalent circuit including an impedance element and an admittance element of a core and a sheath for each phase of an underground power cable; establishing a voltage and current equation for the core and the sheath of the cable by applying a distributed parameter circuit analysis method for each section about the fault point in the equivalent circuit; establishing an equation of a fault distance using a fault condition for an entire system and the voltage and current equation; and calculating the fault distance using the equation of the fault distance and a source side information and a load side information.

### BACKGROUND OF THE INVENTION

The present invention relates to a method for locating a line-to-ground fault point of an underground power cable system, and more particularly to a method for locating a line-to-ground fault point of an underground power cable system wherein a capacitive element of a cable which should not be ignored in case of an underground power cable is considered to accurately obtain a fault distance even when an arrangement of the cable and a fault resistance are changed.

Along with a recent economic growth, a change in a social environment to a high-tech information age requires a stable electric power supply of a large amount of an electric power. In order to satisfy the necessity, the electric power is transmitted and distributed using an underground power cable system. In addition, the underground power cable system applied to a city area and an industrial system improves an appearance of a residential environment as well as a reliability of the electric power supply. Moreover, the underground power cable system may transmit a large electric power, avoid a danger caused by a natural disaster and reduce various accidents caused by human error. However, when a fault occurs on a cable line, it is difficult to detect where a fault point is located and to perform a management and maintenance such as fixing the fault since the cable is buried underground.

While latest transmission/distribution system requires a faster and more accurate fault point locating method, it is disadvantageous that a long section where the underground power cable system is installed should be dug when a certain fault occurs as described above in case of the underground power cable system and a protective layer and a sheath layer protecting a surface of the cable should be checked. Therefore, locating and fixing the fault point of the underground power cable system is more difficult and important issue than an aerial transmission system, and a faster and more accurate fault point locating method that may be applied to the underground power cable system has been proposed.

Conventional methods for locating a fault point of an underground power cable system may be classified into a terminal method and a tracer method (E. C. Bason, “Computerized Underground Cable Fault Location Expertise,” Proceedings of the 1994 IEEE Power Engineering Society, pp. 376-382, April 1994). The terminal method for locating a fault point, which is performed at one terminal or both terminals of the underground line, is generally used to approximately locate the fault point. In accordance with the tracer method for locating a fault point, an audio frequency band or an electromagnetic signal is applied to the faulty line to trace the faulty line in order to find an accurate fault point after finding a faulty section using the terminal method. On the other hand, a method wherein an artificial intelligence method is applied using a traveling wave for calculating a fault distance by measuring a harmonic element traveling along the line when a fault occurs in the line (J. H. Sun, “Fault Location of Underground Cables Using Travelling wave,” Trans. KIEE, pp. 1972-1974, July 2000), a method wherein a fuzzy logic and wavelet analysis are combined (J. Moshtagh, R. K. Aggarwal, “A new approach to fault location in a single core underground cable system using combined fuzzy logic & wavelet analysis,” The Eight IEE International Conference on Developments In Power System Protection, pp. 228-231, April 2004), a method using a neuro-fuzzy wherein a neuro-network for inferring through a learning and inference by a probability are combined (K. H. Kim, J. B. Lee, Y. H. Jeong, “Fault Location Using Neuro_Fuzzy for the Line-to-Ground Fault in Combined Transmission Lines with Underground Power Cables,” Trans. KIEE, pp. 602-609, October 2003) have been proposed.

However, in case of a single core coaxial cable which consists of a core and a sheath, while an inductance thereof is one third of an aerial cable, a capacitance is 20 to 30 times larger than the aerial cable. Therefore, since a capacitive element cannot be ignored in an analysis of the underground power cable, an accurate fault distance cannot be estimated by the above-described conventional method even when the arrangement of the cable and the fault resistance are changed.

### SUMMARY OF THE INVENTION

It is an object of the present invention to provide a novel method for locating a line-to-ground fault point which may be applied to a line-to-ground fault of an underground power cable system by utilizing a distributed parameter analysis theory which is applied to a long distance transmission line analysis method in order to consider a capacitive element in an analysis of the underground power cable.

In order to achieve the above-described object of the present invention, there is provided a method for locating a line-to-ground fault point of an underground power cable system, the method comprising steps of: modeling an equivalent circuit including an impedance element and an admittance element of a core and a sheath for each phase of an underground power cable; establishing a voltage and current equation for the core and the sheath of the cable by applying a distributed parameter circuit analysis method for each section about the fault point in the equivalent circuit; establishing an equation of a fault distance using a fault condition for an entire system and the voltage and current equation; and calculating the fault distance using the equation of the fault distance and a source side information and a load side information.

In accordance with the present invention, the step of establishing the voltage and current equation comprises decreasing a coefficient of the voltage and current equation using a relationship between a voltage and current differential equation obtained by the distributed parameter circuit analysis method and a sequence equation obtained by a hyperbolic function transformation, and the step of establishing the equation of the fault distance comprises expressing an unknown parameter of the voltage and current equation as an equation according to the fault distance.

### BRIEF DESCRIPTION OF THE DRAWINGS

FIGS. 1a and 1b are diagrams exemplifying an example of a structure and an installation method of an underground power cable, respectively.

FIG. 2 is a circuit diagram illustrating a cable model of a distributed parameter circuit.

FIG. 3 is a circuit diagram illustrating an equivalent circuit when a fault occurs in an underground power cable system.

FIG. 4 is a circuit diagram illustrating a voltage-current relationship at a fault point assuming that a core-to-sheath to ground fault occurs in phase a.

FIG. 5 is a diagram illustrating a cable simulation system using a PSCAD/EMTDC.

FIGS. 6a through 6c are diagrams illustrating a section and an arrangement of a tri-phase single core coaxial cable used for a simulation of a method for locating a line-to-ground fault point in accordance with the present invention.

FIG. 7 is a graph illustrating an estimated error at each fault point according to a result obtained by calculating a fault distance by varying a fault resistance at each fault point when the cable is arranged in equilateral triangular shape.

FIG. 8 is a graph illustrating an estimated error at each fault point according to a result obtained by calculating a fault distance by varying a fault resistance at each fault point when the cable is arranged in equilateral horizontal shape.

### DETAILED DESCRIPTION OF THE INVENTION

Preferred embodiments of the present invention will now be described in detail with reference to the accompanied drawings.

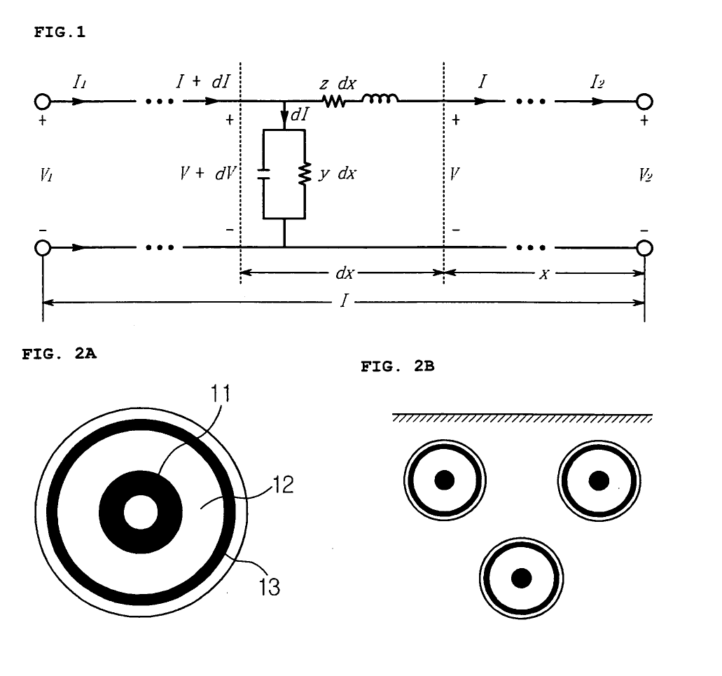

FIGS. 1a and 1b are diagrams exemplifying an example of a structure and an installation method of an underground power cable, respectively.

As shown in FIG. 1a, an underground power cable corresponds to an underground power cable wherein two conductors consisting of a core 11 and a sheath 13 are isolated by an insulator 12. Therefore, in case of the underground power cable, mutual impedance and admittance exist between each conductor. That is, an element between the cores, an element between the core and the sheath, and an element between of the sheaths of each phase exist. In addition, a tri-phase single core coaxial cable may be installed underground in unilateral triangular and horizontal arrangements, and FIG. 1b exemplifies a method wherein the tri-phase single core coaxial cable is installed in the unilateral triangular arrangement.

Prior to describing a method for locating a fault point of a underground table based on a distributed parameter analysis method in detail, a cable model according to the distributed parameter analysis method will be described below.

The impedance and admittance of the underground power cable correspond to a variance parameter distributed among a small section Δx of the cable line. A general form of a small displacement dx is as shown in FIG. 2, and a series impedance of the small section is assumed to be zdx and a parallel impedance of the small section is assumed to be ydx in this case.

Equation 1 may be obtained when Kirchhoff's Voltage Law and Kirchhoff's Current Law are applied to the small section.
dV=Izdx
dI=(V+dV)ydx˜Vydx [Equation 1]

When a product of unknown quantity differentiated in the equation 1, two first order linear differential equations are obtained as shown in Equation 2 below.

$$\frac{ⅆ V}{ⅆ x} = zI \\ \frac{ⅆ I}{ⅆ x} = yV \qquad [ Equation 2 ]$$

In addition, second order linear differential equations are obtained from the equation 2 as shown in equation 3 below.

$$\frac{{ⅆ}^{2} V}{ⅆ {x}^{2}} = yzV = {γ}^{2} V \\ \frac{{ⅆ}^{2} I}{ⅆ {x}^{2}} = yzI = {γ}^{2} I \qquad [ Equation 3 ]$$

When a typical solution for linear differential equation is used, a characteristic equation of s²−γ²=0 is determined, and roots of the characteristic equation s₁,s₂=±γ may be obtained. Therefore, a general solution for a voltage is shown in equation 4 below.

$$\begin{matrix}V = {k}_{1} {ⅇ}^{γ x} + {k}_{2} {ⅇ}^{- γ x} \\ = ( {k}_{1} + {k}_{2} ) \frac{{ⅇ}^{γ x} + {ⅇ}^{- γ x}}{2} + ( {k}_{1} - {k}_{2} ) \frac{{ⅇ}^{γ x} - {ⅇ}^{- γ x}}{2} \\ = {K}_{1} cosh γ x + {K}_{2} sinh γ x\end{matrix} \qquad [ Equation 4 ]$$

Similarly, a general solution for a current may be expressed as equation 5 below.
I=K₃ cos hγx+K₄ sin hγx [Equation 5]

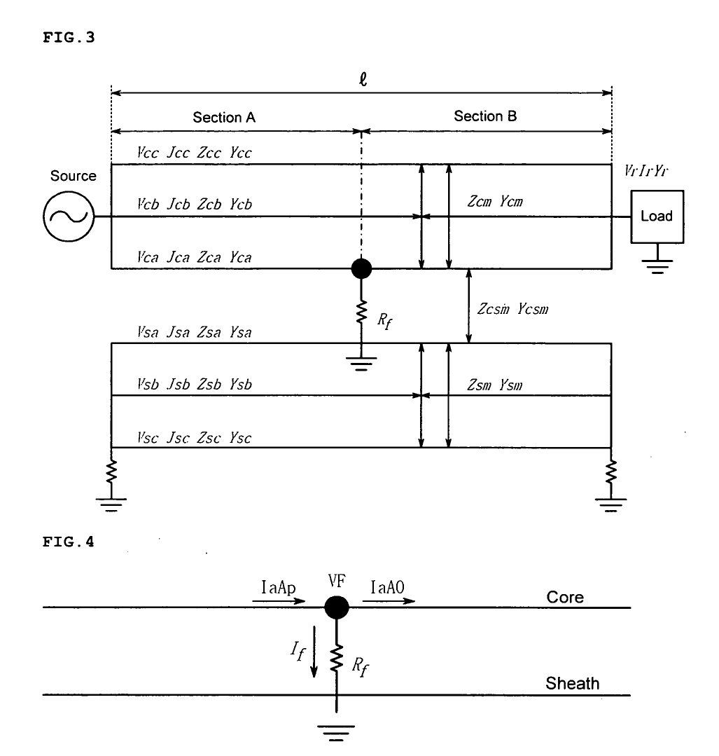

FIG. 3 is a circuit diagram illustrating an equivalent circuit when a fault occurs in an underground power cable system. A type of the fault shown in FIG. 3 corresponds to a core-sheath to ground fault wherein both the core and the sheath are connected to ground.

When such fault occurs, the cable system may be divided into two sections about the fault point as shown in FIG. 3. Section A corresponds to a portion from a source terminal to the fault point, and section B corresponds to a portion from the fault point to a load terminal. As described above, an analysis for the section A is performed by applying the distributed parameter circuit analysis method. A voltage and current equation of the section A may be expressed as equations 6 to 9.

$$\begin{matrix}- ( \begin{matrix}\partial {V}_{ca} / \partial x \\ \partial {V}_{cb} / \partial x \\ \partial {V}_{cc} / \partial x\end{matrix} ) = ( \begin{matrix}{Z}_{ca} & {Z}_{c m} & {Z}_{c m} \\ {Z}_{c m} & {Z}_{c b} & {Z}_{c m} \\ {Z}_{c m} & {Z}_{c m} & {Z}_{cc}\end{matrix} ) ( \begin{matrix}{I}_{ca} \\ {I}_{cb} \\ {I}_{cc}\end{matrix} ) + ( \begin{matrix}{Z}_{csa} & {Z}_{csm} & {Z}_{csm} \\ {Z}_{csm} & {Z}_{csb} & {Z}_{csm} \\ {Z}_{csm} & {Z}_{csm} & {Z}_{c sc}\end{matrix} ) ( \begin{matrix}{I}_{sa} \\ {I}_{sb} \\ {I}_{sc}\end{matrix} ) & [ Equation 6 ] \\ - ( \begin{matrix}\partial {V}_{sa} / \partial x \\ \partial {V}_{sb} / \partial x \\ \partial {V}_{sc} / \partial x\end{matrix} ) = ( \begin{matrix}{Z}_{csa} & {Z}_{csm} & {Z}_{csm} \\ {Z}_{csm} & {Z}_{csb} & {Z}_{csm} \\ {Z}_{csm} & {Z}_{csm} & {Z}_{c sc}\end{matrix} ) ( \begin{matrix}{I}_{ca} \\ {I}_{cb} \\ {I}_{cc}\end{matrix} ) + ( \begin{matrix}{Z}_{sa} & {Z}_{s m} & {Z}_{s m} \\ {Z}_{sm} & {Z}_{sb} & {Z}_{s m} \\ {Z}_{s m} & {Z}_{c m} & {Z}_{sc}\end{matrix} ) ( \begin{matrix}{I}_{sa} \\ {I}_{sb} \\ {I}_{sc}\end{matrix} ) & [ Equation 7 ] \\ - ( \begin{matrix}\partial {I}_{ca} / \partial x \\ \partial {I}_{cb} / \partial x \\ \partial {I}_{cc} / \partial x\end{matrix} ) = ( \begin{matrix}{Y}_{ca} & {Y}_{c m} & {Y}_{c m} \\ {Z}_{c m} & {Z}_{c b} & {Y}_{c m} \\ {Y}_{c m} & {Y}_{c m} & {Y}_{cc}\end{matrix} ) ( \begin{matrix}{V}_{ca} \\ {V}_{cb} \\ {V}_{cc}\end{matrix} ) + ( \begin{matrix}{Y}_{csa} & {Y}_{csm} & {Y}_{csm} \\ {Y}_{csm} & {Y}_{csb} & {Y}_{csm} \\ {Y}_{csm} & {Y}_{csm} & {Y}_{c sc}\end{matrix} ) ( \begin{matrix}{V}_{sa} \\ {V}_{sb} \\ {V}_{sc}\end{matrix} ) & [ Equation 8 ] \\ - ( \begin{matrix}\partial {I}_{sa} / \partial x \\ \partial {I}_{sb} / \partial x \\ \partial {I}_{sc} / \partial x\end{matrix} ) = ( \begin{matrix}{Y}_{csa} & {Y}_{csm} & {Y}_{csm} \\ {Y}_{csm} & {Y}_{csb} & {Y}_{csm} \\ {Y}_{csm} & {Y}_{csm} & {Y}_{c sc}\end{matrix} ) ( \begin{matrix}{V}_{ca} \\ {V}_{cb} \\ {V}_{cc}\end{matrix} ) + ( \begin{matrix}{Y}_{sa} & {Y}_{s m} & {Y}_{s m} \\ {Y}_{sm} & {Y}_{sb} & {Y}_{s m} \\ {Y}_{s m} & {Y}_{c m} & {Y}_{sc}\end{matrix} ) ( \begin{matrix}{V}_{sa} \\ {V}_{sb} \\ {V}_{sc}\end{matrix} ) & [ Equation 9 ]\end{matrix}$$

where

Z_{ca}, Z_{cb}, and Z_{cc} are self-impedances of cores in a, b and c phase;

Z_{csa}, Z_{csb}, and Z_{csc} are mutual impedances between core and sheath of a, b and c phase respectively;

Z_{csm} is a mutual impedance between core and sheath of different phases;

Zₛₐ, Z_{sb} and Z_{sc} are self-impedances of sheaths in a, b and c phase;

Y_{ca}, Y_{cb} and Y_{cc} are self-admittances of cores in a, b and c phase;

Y_{csa}, Y_{csb} and Y_{csc} are mutual admittances between the cores and sheaths in a, b and c phase;

Y_{csm} is a mutual admittance between the cores and the sheaths of different phases;

Yₛₐ, Y_{sb} and Y_{sc} are self-admittances of the sheaths in a, b and c phase;

V_{ca}, V_{cb} and V_{cc} are core voltages of a, b and c phase;

Vₛₐ, V_{sb} and V_{sc} are sheath voltages of a, b and c phase;

I_{ca}, I_{cb} and I_{cc} are core currents of a, b and c phase; and

Iₛₐ, I_{sb} and I_{sc} are sheath currents of a, b and c phase.

The above equations 6 through 9 may be simplified as equations 10 through 13.
−∂Vc_{abc}/∂x=Zc_{abc}/c_{abc}Zcs_{abc}/s_{abc} [Equation 10]
−∂Vs_{abc}i∂x=Zcs_{abc}lc_{abc}+Zs_{abc}ls_{abc} [Equation 11]
−∂lc_{abc}l∂x=Yc_{abc}Vc_{abc}+Ycs_{abc}Vs_{abc} [Equation 12]
−∂ls_{abc}l∂x=Ycs_{abc}Vc_{abc}+Ys_{abc}Vs_{abc} [Equation 13]

The equations 10 through 13 may be expressed in a matrix form as in equation 14 after applying a symmetric conversion in a zero-sequence, a positive-sequence and a negative-sequence.

$$- [ \begin{matrix}\overline{V} {c}_{012} \\ \overline{V} {s}_{012} \\ \overline{I} {c}_{012} \\ \overline{I} {s}_{012}\end{matrix} ] \\ = [ \begin{matrix}0 & 0 & {Zc}_{012} & {Zcs}_{012} \\ 0 & 0 & {Zcs}_{022} & {Zs}_{012} \\ {Yc}_{012} & {Ycs}_{012} & 0 & 0 \\ {Ycs}_{012} & {Ys}_{012} & 0 & 0\end{matrix} ] [ \begin{matrix}{Vc}_{012} \\ {Vs}_{012} \\ {Ic}_{012} \\ {Is}_{012}\end{matrix} ] \qquad [ Equation 13 ]$$

The equation 14 is an expression for a zero-sequence circuit, a positive-sequence circuit and a negative-sequence circuit. When characteristic roots for the zero-sequence circuit are defined as α₀ and β₀, characteristic roots for the positive-sequence circuit as α₁ and β₁, and characteristic roots for the negative-sequence circuit are defined as α₂ and β₂, the voltage and the current of the section A may be obtained by the distributed parameter analysis method.

Equations 15 through 18 are zero-sequence voltages and currents equations, wherein subscript 0 of each term of the equations 15 through 18 denotes the zero-sequence.
V_{cA0}(x)=A₀ cos hα₀x+B₀ sin hα₀x+C₀ cos hβ₀x+D₀ sin hβ₀x [Equation 15]
V_{xA0}(x)=A₀′ cos hα₀x+B₀′ sin hα₀x+C₀′ cos hβ₀x+D₀′ sin hβ₀x [Equation 16]
I_{cA0}(x)=α₀ cos hα₀x+b₀ sin hα₀x+c₀ cos hβ₀x+d₀ sin hβ₀x [Equation 17]
I_{xA0}(x)=e₀ cos hα₀x+₀ sin hα₀x+g₀ cos hβ₀x+h₀ sin hβ₀x [Equation 18]

Voltage and current equations for the positive-sequence and the negative-sequence may be expressed similar to the equations 15 through 18 by replacing subscripts of each term of the equations 15 through 18 with 1 and 2, respectively. Accordingly, voltage and current equations of the core and the sheath for the section A may be derived, and the number of unknown quantities is sixteen for the zero-sequence, the positive-sequence and the negative-sequence, respectively.

Therefore, as described above, forty eight coefficients should be obtained in order to obtain a solution of a hyperbolic function for the section A. However, since values given from an underground power cable simulation program is a voltage and a current of each sequence element, the number of the values is six in total, and the number of fault conditions are only twenty four in case of a line-to-ground fault of the cable system including the section B. Therefore, forty eight coefficients should be reduced to twelve in order to analyze the section A. In accordance with the present invention, relationship between the equations 10 through 13 which are differential equations of the voltage and the current obtained by the distributed parameter circuit analysis and the equations 15 through 18 which are sequence equations obtained through hyperbolic function transformation are utilized in order to reduce the forty eight coefficients to twelve.

When the hyperbolic function of the equations 15 through 18 are substituted for the equations 10 through 13, the zero-sequence is expressed as an equation of A₀, B₀, C₀ and D₀, the positive-sequence is expressed as an equation of A₁, B₁, C₁ and D₁, and the negative-sequence is expressed as an equation of A₂, B₂, C₂ and D₂, as shown in table 1 below.

TABLE 1

| zero-sequence | positive-sequence | negative-sequence |
|---|---|---|
| A₀′ = C₁₀A₀ | A₁′ = C₁₁A₁ | A₂′ = C₁₂A₂ |
| B₀′ = C₁₀B₀ | B₁′ = C₁₁B₁ | B₂′ = C₁₂B₂ |
| C₀′ = C₂₀C₀ | C₁′ = C₂₁C₁ | C₂′ = C₂₂C₂ |
| D₀′ = C₂₀D₀ | D₁′ = C₂₁D₁ | D₂′ = C₁₂D₂ |
| a₀ = C₃₀B₀ | a₁ = C₃₁B₁ | a₂ = C₃₂B₂ |
| b₀ = C₃₀A₀ | b₁ = C₃₁A₁ | b₂ = C₃₂A₂ |
| C₀ = C₄₀D₀ | C₁ = C₄₁D₁ | C₂ = C₄₂D₂ |
| d₀ = C₄₀C₀ | d₁ = C₄₁C₁ | d₂ = C₄₂C₂ |
| e₀ = C₅₀B₀ | e₁ = C₅₁B₁ | e₂ = C₅₂B₂ |
| f₀ = C₅₀A₀ | f₁ = C₅₁A₁ | f₂ = C₅₂A₂ |
| g₀ = C₆₀D₀ | g₁ = C₆₁D₁ | g₂ = C₆₂D₂ |
| h₀ = C₆₀C₀ | h₁ = C₆₁C₁ | h₂ = C₆₂C₂ |

By substituting the above equations, the voltage and current equation may be expressed in a matrix form as equations 19 through 21.

$$\begin{matrix}( \begin{matrix}V \text{?} ( x ) \\ V \text{?} ( x ) \\ I \text{?} ( x ) \\ I \text{?} ( x )\end{matrix} ) = ( \begin{matrix}cosh {α}_{0} x & sinh {α}_{0} x & cosh {β}_{0} x & sinh {β}_{0} x \\ {C}_{10} cosh {α}_{0} x & {C}_{10} sinh {α}_{0} x & {C}_{20} cosh {β}_{0} x & {C}_{20} sinh {β}_{0} x \\ {C}_{30} sinh {α}_{0} x & {C}_{30} cosh {α}_{0} x & {C}_{40} sinh {β}_{0} x & {C}_{40} cosh {β}_{0} x \\ {C}_{50} sinh {α}_{0} x & {C}_{50} cosh {α}_{0} x & {C}_{60} sinh {β}_{0} x & {C}_{60} cosh {β}_{0} x\end{matrix} ) ( \begin{matrix}{A}_{0} \\ {B}_{0} \\ {C}_{0} \\ {D}_{0}\end{matrix} ) & [ Equation 19 ] \\ ( \begin{matrix}V \text{?} ( x ) \\ V \text{?} ( x ) \\ I \text{?} ( x ) \\ I \text{?} ( x )\end{matrix} ) = ( \begin{matrix}cosh {α}_{1} x & sinh {α}_{1} x & cosh {β}_{1} x & sinh {β}_{1} x \\ {C}_{11} cosh {α}_{1} x & {C}_{11} sinh {α}_{1} x & {C}_{21} cosh {β}_{1} x & {C}_{21} sinh {β}_{1} x \\ {C}_{31} sinh {α}_{1} x & {C}_{31} cosh {α}_{1} x & {C}_{41} sinh {β}_{1} x & {C}_{41} cosh {β}_{1} x \\ {C}_{51} sinh {α}_{1} x & {C}_{51} cosh {α}_{1} x & {C}_{61} sinh {β}_{1} x & {C}_{61} cosh {β}_{1} x\end{matrix} ) ( \begin{matrix}{A}_{1} \\ {B}_{1} \\ {C}_{1} \\ {D}_{1}\end{matrix} ) & [ Equation 20 ] \\ ( \begin{matrix}V \text{?} ( x ) \\ V \text{?} ( x ) \\ I \text{?} ( x ) \\ I \text{?} ( x )\end{matrix} ) = ( \begin{matrix}cosh {α}_{2} x & sinh {α}_{2} x & cosh {β}_{2} x & sinh {β}_{2} x \\ {C}_{12} cosh {α}_{2} x & {C}_{12} sinh {α}_{2} x & {C}_{22} cosh {β}_{2} x & {C}_{22} sinh {β}_{2} x \\ {C}_{32} sinh {α}_{2} x & {C}_{32} cosh {α}_{2} x & {C}_{42} sinh {β}_{2} x & {C}_{42} cosh {β}_{2} x \\ {C}_{52} sinh {α}_{2} x & {C}_{52} cosh {α}_{2} x & {C}_{62} sinh {β}_{2} x & {C}_{62} cosh {β}_{2} x\end{matrix} ) ( \begin{matrix}{A}_{2} \\ {B}_{2} \\ {C}_{2} \\ {D}_{2}\end{matrix} ) \\ \text{?} \text{indicates text missing or illegible when filed} & [ Equation 21 ]\end{matrix}$$

When analysis method for the section A is applied to the section B, a voltage and current equation is obtained in a form of the hyperbolic function for the section B. The voltage and current equation of the section B may be expressed as the equations 19 through 21, wherein the four unknown quantities A, B AND C and D are substituted by four unknown quantities E, F, G and H.

A₀, B₀, C₀, D₀, E₀, F₀, G₀ and H₀ are unknown parameters of the zero-sequence, A₁, B₁, C₁, D₁, E₁, F1, G₁ and H₁ are unknown parameters of the positive-sequence, and A₂, B₂, C₂, D₂, E₂, F2, G₂ and H₂ are unknown parameters of the negative-sequence. Sequence constants calculated in the coefficients reduction process are shown in table 2 below.

TABLE 2

| | |
|---|---|
| zero-sequence | ${C}_{10} = \frac{{{α}_{0}}^{2} - {Z}_{c 0} {Y}_{c 0} - {Z}_{cs 0} {Y}_{cs 0}}{{Z}_{c 0} {Y}_{cs 0} + {Z}_{cs 0} {Y}_{s 0}} , {C}_{40} = - \frac{{Y}_{c 0} + {Y}_{cs 0} {C}_{20}}{{β}_{0}}$ |
| | ${C}_{20} = \frac{{{β}_{0}}^{2} - {Z}_{c 0} {Y}_{c 0} - {Z}_{cs 0} {Y}_{cs 0}}{{Z}_{c 0} {Y}_{cs 0} + {Z}_{cs 0} {Y}_{s 0}} , {C}_{50} = - \frac{{Y}_{cs 0} + {Y}_{s 0} {C}_{10}}{{α}_{0}}$ |
| | ${C}_{30} = - \frac{{Y}_{c 0} + {Y}_{cs 0} {C}_{10}}{{α}_{0}} , {C}_{60} = - \frac{{Y}_{cs 0} + {Y}_{s 0} {C}_{20}}{{β}_{0}}$ |
| positive-sequence | ${C}_{11} = \frac{{{α}_{1}}^{2} - {Z}_{c1} {Y}_{c 1} - {Z}_{cs1} {Y}_{cs 1}}{{Z}_{c 1} {Y}_{cs1} + {Z}_{cs 1} {Y}_{s 1}} , {C}_{41} = - \frac{{Y}_{c1} + {Y}_{cs 1} {C}_{21}}{{β}_{1}}$ |
| | ${C}_{21} = \frac{{{β}_{1}}^{2} - {Z}_{c1} {Y}_{c 1} - {Z}_{cs1} {Y}_{cs 1}}{{Z}_{c 1} {Y}_{cs1} + {Z}_{cs 1} {Y}_{s 1}} , {C}_{51} = - \frac{{Y}_{c s 1} + {Y}_{s 1} {C}_{11}}{{α}_{1}}$ |
| | ${C}_{31} = - \frac{{Y}_{c1} + {Y}_{cs 1} {C}_{11}}{{α}_{1}} , {C}_{61} = - \frac{{Y}_{cs 1} + {Y}_{s 1} {C}_{21}}{{β}_{1}}$ |
| negative-sequence | ${C}_{12} = \frac{{{α}_{2}}^{2} - {Z}_{c2} {Y}_{c 2} - {Z}_{cs2} {Y}_{cs 2}}{{Z}_{c 2} {Y}_{cs2} + {Z}_{cs 2} {Y}_{s 2}} , {C}_{42} = - \frac{{Y}_{c2} + {Y}_{cs 2} {C}_{22}}{{β}_{2}}$ |
| | ${C}_{22} = \frac{{{β}_{2}}^{2} - {Z}_{c2} {Y}_{c 2} - {Z}_{cs2} {Y}_{cs 2}}{{Z}_{c 2} {Y}_{cs2} + {Z}_{cs 2} {Y}_{s 2}} , {C}_{52} = - \frac{{Y}_{c s2} + {Y}_{s 2} {C}_{12}}{{α}_{2}}$ |
| | ${C}_{32} = - \frac{{Y}_{c2} + {Y}_{cs 2} {C}_{12}}{{α}_{2}} , {C}_{62} = - \frac{{Y}_{cs 2} + {Y}_{s 2} {C}_{22}}{{β}_{2}}$ |

Finally, when the total length of the cable is 1, a distance from the source terminal to the fault point is p, an end point of the section A is x=p, and a starting point of the section B is y=0.

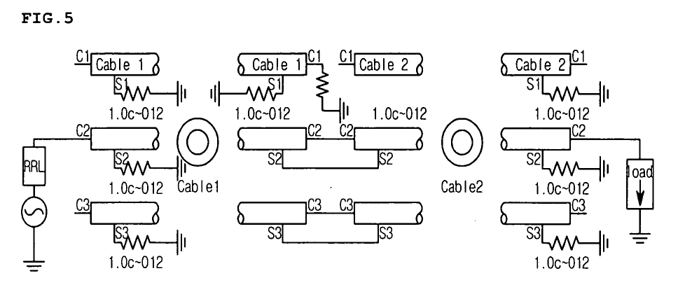

The fault condition will be analyzed below. While various types of faults may occur in a cable, a core-to-sheath to ground fault which is most common will be considered as shown in FIG. 4.

In order to obtain twenty four unknown quantities obtained above, the entire condition of the fault system is analyzed. Analyzed conditions are as follows.

Firstly, conditions being satisfied for each sequence, at the source terminal, are: 1) a core voltage is identical to a source voltage, 2) a core current is identical to a source current, and 3) a sheath voltage is 0 when a grounding resistance is 0 and is three times the product of the grounding resistance and a sheath current otherwise. A condition being satisfied at the fault point is: 4) a core voltage of the section A is identical to that of the section B, and conditions being satisfied at the load terminal are: 5) the core current is identical to a product of a load admittance and the core voltage, and 6) the sheath voltage is 0 when the grounding resistance is 0 and is three times the product of the grounding resistance and the sheath current otherwise.

Secondly, conditions being satisfied for each phase at the fault point are: 1) the sheath voltage of the section A is 0 when the phase a is faulty, 2) the sheath voltage of the section B is 0 when the phase a is faulty, 3) the core current of the section A is identical to that of the section B when the phase b is not faulty, 4) the core current of the section A is identical to that of the section B when the phase c is not faulty, 5) the sheath current of the section A is identical to that of the section B when the phase b is not faulty, and 6) the sheath current of the section A is identical to that of the section B when the phase c is not faulty.

The above conditions may be summarized to twenty four equations as shown in table 3.

TABLE 3
Sequence conditions (18)

| | | |
|---|---|---|
| V_{cA0}(0) = V_{S0} | V_{cA1}(0) = V_{S1} | V_{cA2}(0) = V_{S2} |
| I_{cA0}(0) = I_{S0} | I_{cA1}(0) = I_{S1} | I_{cA2}(0) = I_{S2} |
| V_{sA0}(0) = 0 | V_{sA1}(0) = 0 | V_{sA2}(0) = 0 |
| V_{cA0}(p) = V_{cB0}(0) | V_{cA1}(p) = V_{cB1}(0) | V_{cA2}(p) = V_{cB2}(0) |
| I_{cB0}(l − p) = Yᵣ₀V_{cB0}(l − p) | I_{cB1}(l − p) = | I_{cB2}(l − p) = |
| | Yᵣ₁V_{cB1}(l − p) | Yᵣ₂V_{cB2}(l − p) |
| V_{sB0}(l − p) = 0 | V_{sB1}(l − p) = 0 | V_{SB2}(l − p) = 0 |

Phase conditions (6)

| | | |
|---|---|---|
| V_{sAa}(p) = 0 | V_{sBa}(p) = 0 | V_{cAb}(p) = I_{cBb}(0) |
| I_{cAc}(p) = I_{cBc}(0) | I_{sAb}(p) = I_{sBb}(0) | I_{sAc}(p) = I_{sBc}(0) |

Twenty four equations for obtaining the entire unknown parameters may be established by using the above twenty four conditions, and the equations is expressed as a function of the fault distance p.

A voltage V_{f} at the fault point may be obtained from a product of a fault current I_{f} and a fault resistance R_{f} in FIG. 4, the voltage at the fault point is expressed as equation 22 below.
V_{f}=I_{f}×R_{f} [Equation 22]

When the equation 22 is applied to the faulty phase of the underground power cable, a function of the fault distance p and fault resistance R_{f} is obtained as shown in FIG. 23.
f(p,R_{f})=Vα_{Ap}−(1α_{Ap}−1α_{A0})R_{f}=0 [Equation 23]
where
Vα_{Ap}=V_{cA0}(p)+V_{cA1}(p)+V_{cA2}(p)
Iα_{Ap}=I_{cA0}(p)+I_{cA1}(p)+I_{cA2}(p)
Iα_{B0}I_{cB0}(0)+I_{cB1}(0)+I_{cB2}(0)

In addition, when the equation 23 is divided into a real part and an imaginary part in order to obtain a solution of the equation 23, equation 24 is obtained.
f(p,R_{f})=f,(p,R_{f})+jf,(p,R_{f})=0 [Equation 24]

The real part and the imaginary part in the equation 24 should satisfy a condition of being zero, respectively. Therefore, equation 25 is obtained.
f,(p,R_{f})=0, f,(p,R_{f})=0 [Equation 25]

Finally, in order to obtain the fault distance p, a method such as Newton-Raphson iteration method may be applied until a convergence value for the fault distance is no more than 0.0001.

FIG. 5 is a diagram illustrating a cable simulation system using a PSCAD/EMTDC. A type of the cable in the simulation system is a kraft type single core coaxial cable consisting of a core and a sheath, wherein a sectional area thereof is 2000 mm² , and a voltage of the underground power cable system is 154 kV. A total length of the cable is 4 km, and an impedance and an admittance of the subject cable are obtained using PSCAD/EMTDC Ver. 4.1 subroutine.

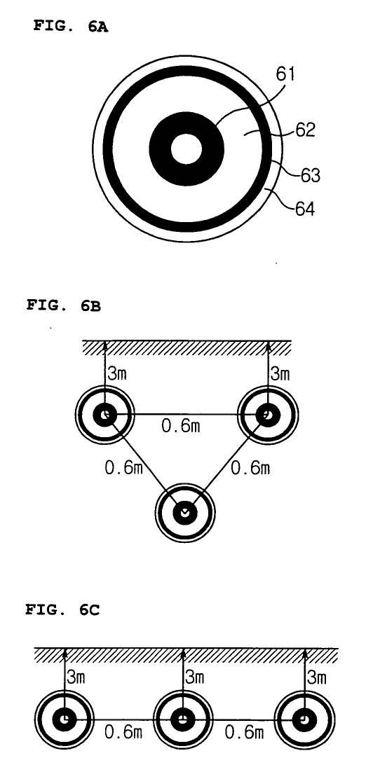

FIGS. 6a illustrates a section of a tri-phase single core coaxial cable consisting of a core 61, an insulator 62, a sheath 63 and an exterior cover 64 as an insulator, and such cable is buried and operating 3 meters underground. With respect to an arrangement of the cable, a unilateral triangular structure as shown in FIG. 6b, and a unilateral horizontal structure as shown in FIG. 6c are considered.

In order to obtain a result of the simulation, a core-to-sheath to ground fault is assumed as a type of the fault of the cable, and a fault phase is assumed to be the phase a. In addition, a resistivity of the core 61 is 1.7241e⁻⁸ Ωm, a relative magnetic permeability thereof is 1.0, a relative magnetic permeability of the insulator 62 is 1.0, a relative permittivity thereof is 3.4, a resistivity of the sheath 63 is 2.84e⁻⁸ Ωm, a relative magnetic permeability thereof is 1.0, a relative magnetic permeability of exterior cover 64 is 1.0, and a relative permittivity thereof is 3.5. A radius of an insulator inside the core 61 is 0.007 m, a radius to the core 61 is 0.02895 m, a radius to the insulator 62 is 0.4345 m, a radius to the sheath 63 is 0.4515 m, and an entire radius to the exterior cover 64 is 0.4965 m. As shown in FIGS. 6b and 6c, a distance between neighboring single core cables is 0.6 m.

In addition, nine fault distances are simulated by increasing the fault distance by 0.1 pu from 0.1 pu to 0.9 pu for two cable arrangements shown in FIGS. 6n and 6c, and four fault resistance, namely 0.1Ω, 10Ω, 30Ω and 50Ω, are simulated, thereby simulating thirty six cases by PSCAD/EMTDC. In each case, a core voltage and a core current have been obtained, and a phase is obtained using a DFT (Discrete Fourier Transform) having data window of a single period. An error of the fault distance calculation is obtained form equation 26.

$$Error ( \% ) = \frac{\vert estimated distance - actual distance \vert}{total length of cable} \times 100 \qquad [ Equation 26 ]$$

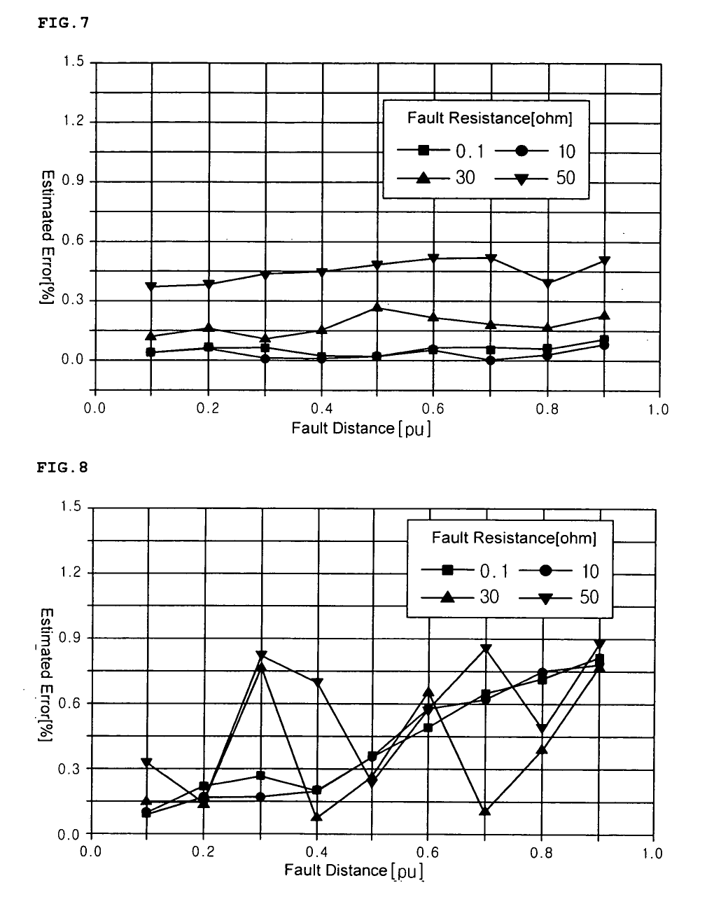

FIGS. 7 and 8 are graphs illustrating a simulation result under the above conditions.

FIG. 7 illustrates an estimated error at each fault point according to the result obtained by calculating a fault distance by varying a fault resistance at each fault point when the cable is arranged in equilateral triangular shape. As shown in FIG. 7, in accordance with the locating method of the present invention, a maximum error is less than 0.6% even when there is a large fault resistance of 50Ω, thereby accurately estimating the fault distance.

FIG. 8 illustrates an estimated error at each fault point according to a result obtained by calculating a fault distance by varying a fault resistance at each fault point when the cable is arranged in equilateral horizontal shape. As shown in FIG. 8, in accordance with the locating method of the present invention, a maximum error is no more than 0.6% even when the fault resistance is no more than 30Ω, and a maximum error is less than 0.9% even when there is a large fault resistance of 50Ω. Therefore, in accordance with the locating method of the present invention, an accurate fault distance may be estimated even in an arrangement wherein a mutual impedance of the each phase of the underground power cable is not parallel.

Referring to FIGS. 7 and 8, in accordance with the method for locating a line-to-ground fault point of an underground power cable system of the present invention, the fault distance may be accurately estimated even when the arrangement of the cable and the fault resistance are changed in locating the fault point of the underground power cable system.

As described above, in accordance with present invention, the distributed parameter circuit analysis theory is employed to consider a capacitive element of the cable in the underground power cable analysis, thereby providing an accurate estimation of the fault distance even when the arrangement of the cable and the fault resistance are varied.

What is claimed is:

1. A method for locating a line-to-ground fault point of an underground power cable system, the method comprising steps of:
modeling an equivalent circuit including an impedance element and an admittance element of a core and a sheath for each phase of an underground power cable;
establishing a voltage and current equation for the core and the sheath of the cable by applying a distributed parameter circuit analysis method for each section about the fault point in the equivalent circuit;
establishing an equation of a fault distance using a fault condition for an entire system and the voltage and current equation; and
calculating the fault distance using the equation of the fault distance and a source side information and a load side information.

2. The method in accordance with claim 1, wherein the step of establishing the voltage and current equation comprises decreasing a coefficient of the voltage and current equation using a relationship between a voltage and current differential equation obtained by the distributed parameter circuit analysis method and a sequence equation obtained by a hyperbolic function transformation.

3. The method in accordance with claim 1, wherein the step of establishing the equation of the fault distance comprises expressing an unknown parameter of the voltage and current equation as an equation according to the fault distance.

4. The method in accordance with claim 1, wherein the voltage and current equation is composed of a voltage and current equation for a section from a source terminal to the fault point, and a voltage and current equation for a section from the fault point to a load terminal, centered at the line-to-ground fault point.

5. The method in accordance with claim 1, wherein the fault condition according to the line-to-ground fault of the system is composed of a condition being satisfied at a source terminal, the fault point and the load terminal, and a condition being satisfied at the fault point of each phase.

6. The method in accordance with claim 1, wherein the step of calculating the fault distance utilizes a relationship between a voltage and a current at the fault point.

7. The method in accordance with claim 6, wherein the step of calculating the fault distance comprises repeatedly applying a Newton-Raphson iteration method until a convergence value for the fault distance is no more than a predetermined value.
